(19) United States
(12) Patent Application Publication
(10) Pub. No.: US 2023/0046847 A1
(43) Pub. Date: Feb. 16, 2023

(54) ELECTROCHROMIC ELEMENT AND DEVICES WITH BULK HETEROJUNCTION LAYER FOR ENHANCED DARK STATE RETENTION

(71) Applicant: NITTO DENKO CORPORATION, Osaka (JP)

(72) Inventor: Liping Ma, San Diego, CA (US)

(21) Appl. No.: 17/760,428

(22) PCT Filed: Feb. 10, 2021
(86) PCT No.: PCT/US21/17509

§ 371 Date: Aug. 9, 2022

Related U.S. Application Data
(60) Provisional application No. 62/975,122, filed on Feb. 11, 2020.

(51) Int. Cl. G02F 1/163; G02F 1/155; G02F 1/1333; G02F 1/1343; G02F 1/1524; G02F 1/1506; G02F 1/153; C23C 14/08; C23C 14/00; C23C 14/34

(52) U.S. Cl. CPC G02F 1/163; G02F 1/155; G02F 1/133345; G02F 1/13439; G02F 1/1524; G02F 1/1506; G02F 1/1533; C23C 14/081; C23C 14/085; C23C 14/0036; C23C 14/34; G02F 2202/16

(57) ABSTRACT

The present disclosure relates to electrochromic elements (10) and devices (110) comprising an electrochromic material layer (114), an insulating layer (116), and a bulk heterojunction layer (118), having one or more optical properties that may be changed upon application of an electric potential. Upon provision of an electric potential above a threshold, electrons and holes may be injected into the electrochromic layer (114) and bulk heterojunction layer (118), and blocked by the insulating layer (116), resulting in an accumulation of the electrons and holes in their respective electrochromic material resulting in a change to the one or more optical properties of the electrochromic materials (114; 118). An opposite electric potential may be provided to reverse the change in the one or more optical properties.

### CROSS-REFERENCE TO RELATED APPLICATIONS

This application claims the benefit of U.S. Provisional Application No. 62/975,122, filed Feb. 11, 2020, which is incorporated by reference herein in its entirety.

### FIELD

The present disclosure relates to electrochromic elements and devices comprising an insulating layer and electrochromic materials having one or more optical properties that may be changed from a first optical property state to a second optical property state upon application of an electric potential.

### BACKGROUND

Electrochromic coatings or materials may be used for several different purposes. One such purpose includes controlling the amount of light and heat passing through a window based on a user-controlled electrical potential that is applied to an electrochromic coating. An electrochromic coating or material may reduce the amount of energy necessary to heat or cool a room and may provide privacy. For example, a clear state of the electrochromic coating or material, having an optical transmission of about 60-80%, may be switched to a darkened state, having an optical transmission of between 0.1-10%, where the energy flow into the room is limited and additional privacy is provided. Due to large amounts of glass found in various types of windows, such as skylights, aircraft windows, automobile windows, and residential and commercial building windows, there may be energy savings provided by the use of an electrochromic coating or material on glass.

Despite the potential benefits that an electrochromic coating or device may provide, various issues may make current electrochromic devices undesirable for some applications. For example, in electrochromic devices utilizing an electrolyte, low ion mobility of the electrolyte may cause reductions in switching speeds and temperature-dependence issues. Ion intercalation may also occur in the electrochromic layer of an electrolyte-based device which causes the device volume to expand, and resultant mechanical stresses may limit the ability to operate between on and off cycles of the device. In such devices, there is a trade-off between high-speed switching and uniform switching because high ion mobility gives a very low internal device resistance for a larger area device, and this may lead to non-uniformity in application of an electric field across the whole device area. A further limitation of some electrochromic devices is the need for continuous application of electrical power in order to retain changes to the optical properties of the electrochromic material. Thus, there remains a need for further contributions in this area of technology.

### SUMMARY

Disclosed herein are electrochromic elements and devices, which include an electrochromic material having one or more optical properties that may change from a first state to a second state upon application of an electric potential. The present disclosure also describes electrochromic elements and devices having an insulating layer that exhibits insulative properties intended for retaining changes to the optical properties of the electrochromic material following application of the electric potential.

Some embodiments include an electrochromic element comprising: a first electrode layer comprising a transparent conductive material; an electrochromic layer comprising a p-type electrochromic material, wherein the electrochromic layer is disposed over and in electrical communication with the first electrode layer; an insulating layer comprising an electrically insulating material with a band gap at least 5 eV and a conductance band edge that is at least 2 eV higher than the insulating material's Fermi level, wherein the electrically insulating material is disposed over and in electrical communication with the electrochromic layer; a bulk heterojunction layer comprising a composite including an n-type electrochromic material and an electrically insulating material, wherein the bulk heterojunction layer is disposed over and in electrical communication with the insulating layer; and a second electrode layer comprising a transparent conductive material, wherein the second electrode layer is disposed over and in electrical communication with the bulk heterojunction layer.

Some embodiments include an electrochromic device comprising: an electrochromic element described herein and a power source in electrical communication with the first electrode layer and the second electrode layer of the electrochromic element, wherein the power source provides an electrical voltage to the device.

In addition, the present disclosure provides methods for the preparation of the electrochromic elements and devices described herein.

### BRIEF DESCRIPTION OF THE DRAWINGS

FIG. 1 is a schematic illustration of one embodiment of an electrochromic element.

FIG. 2 is a schematic illustration of one embodiment of an electrochromic device.

FIG. 3 is a graphic illustration showing the total transmission (T %) as a function of wavelength (nm) of the device of Example CE-1 in an ON state and OFF state.

FIG. 4 is a graphic illustration showing the total transmission (T %) as a function of wavelength (nm) of the device of Example EC-2 in an ON state and OFF state.

FIG. 5 is a graphic illustration showing the on-state switching speed when a forward bias of 4V is applied to devices described herein.

FIG. 6 is a graphic illustration showing the off-state switching speed when a reverse bias of −4V is applied to devices described herein.

FIG. 7 is a graphic illustration showing the electron dissipation out of the n-type EC layer of CE-1 and the BHJ layer of EC-2 once the forward bias is turned off, linear phase.

FIG. 8 is a graphic illustration showing the electron dissipation out of the n-type EC layer of CE-1 and the BHJ layer of EC-2 once the forward bias is turned off, log phase.

FIG. 9 is a schematic of the device used for dark-state retention measurements.

### DETAILED DESCRIPTION

Typically, an electrochromic element comprises a first electrode layer comprising a transparent conductive material. For some electrochromic elements, the electrochromic element further comprises an electrochromic layer, comprising a p-type electrochromic material. The electrochromic element may be disposed over the first electrode layer, meaning that it is a layer above the electrode layer, but that other layers (such as a buffer layer) may be disposed between the electrode layer and the electrochromic layer. The electrochromic layer may be in electrical communication with the first electrode layer. An insulating layer may be disposed over and in electrical communication with the electrochromic layer. The insulating layer may comprise an electrically insulating material, such as a material with a band gap at least 5 eV and/or a conductance band edge that is at least 2 eV higher than the insulating material's Fermi level. Some electrochromic elements further comprise a bulk heterojunction layer comprising a composite including an n-type electrochromic material and an electrically insulating material. The bulk heterojunction layer may be disposed over and in electrical communication with the insulating layer. Such an electrochromic element may further comprise a second electrode layer comprising a transparent conductive material. The second electrode layer may be disposed over and in electrical communication with the bulk heterojunction layer.

As used herein, the term “transparent” includes a property in which the corresponding material transmits or allows light, such as visible or infrared light, to pass through the material. In one aspect, the transmittance of light through the transparent material may be about 50-100%, such as at least about 50%, at least about 60%, at least about 70%, at least about 80%, at least about 90%, at least about 95%, at least about 99%, about 50-60%, about 60-70%, about 70-80%, about 80-90%, about 90-95%, or about 95%-99%.

The term “band gap” (energy gap) as used herein has its ordinary meaning in the art and a person of ordinary skill in the art would recognize the term as including the energy required to promote a bound valence electron to become a conductive electron free to move within a solid layer. The conductive electron may serve as a charge carrier to conduct electrical current.

The term “bulk heterojunction” or “BHJ” as used herein refers to a composite comprising two or more materials with differing electrical properties, which form an interfacial layer. For example, the materials could comprise a p-type electrochromic material and a n-type electrochromic material, a p-type electrochromic material and an electrically insulating material, a n-type electrochromic material and an electrically insulating material, etc.

Use of the term “may” or “may be” should be construed as shorthand for “is” or “is not” or, alternatively, “does” or “does not” or “will” or “will not,” etc. For example, the statement “a buffer layer may be present” should be interpreted as, for example, “In some embodiments, a buffer layer is present,” or “In some embodiments, a buffer layer is not present.”

The present disclosure generally relates to electrochromic elements and devices. The electrochromic devices herein include at least one electrochromic element having one or more optical properties, such as transparency, absorption, or transmittance, that may be changed from a first state to a second state upon application of an electric potential. More particularly, but not exclusively, the present disclosure relates to electrochromic elements and devices comprising ultrathin layers, exhibiting improved on- and off-state transmittance differentiation properties following application of the electric potential.

Generally, an electrochromic element comprises a first electrode and a second electrode. One or more blocking layers (or insulating layers) and one or more electrochromic layers may be disposed between the first electrode and the second electrode. In some cases, a conductive nanostructured metal layer may be disposed on an electrochromic layer. In some embodiments, a buffer layer may be present, e.g. between the first electrode layer and the electrochromic layer. Additional layers, such as a protection layer, may also be present in some embodiments of the electrochromic elements and devices disclosed herein.

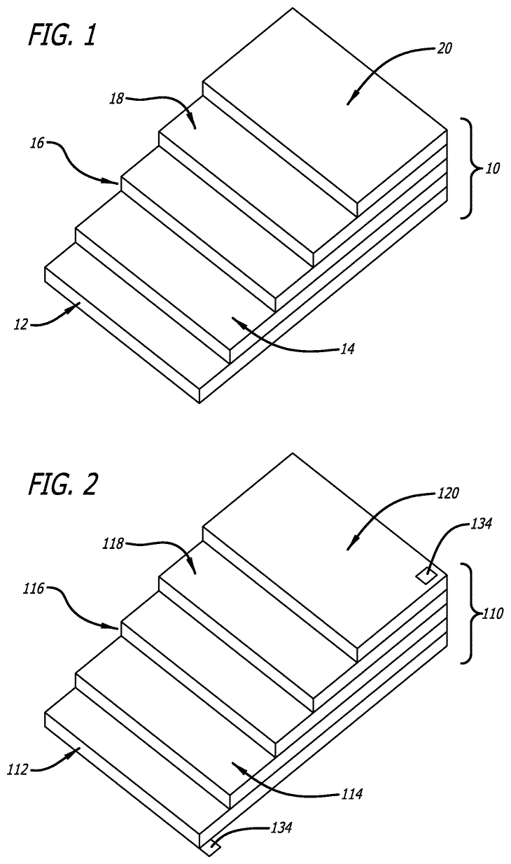

There are many potential configurations for the electrochromic element. One potentially useful configuration is depicted in FIG. 1. An electrochromic element, such as electrochromic element 10 in FIG. 1, comprises (e.g., in the order depicted, from bottom to top): a first electrode layer 12, which is a conductive layer; an electrochromic (EC) layer 14 comprising an electrochromic material; an insulating layer 16, which may also be termed a blocking layer, or a barrier layer, and which comprises an electrically insulative material; a bulk heterojunction (“BHJ”) layer 18, comprising a composite including an electrochromic material and an electrically insulating material; and a second electrode layer 20, which is a conductive material. In some embodiments, the layers comprising the electrochromic element are in electrical and optical communication with one another. In some embodiments, the EC layer and the BHJ layer of the electrochromic element may change from a first state (clear or transparent) to a second state (colored or darkened).

In some embodiments, the recited layers of the element are disposed in the recited order from bottom to top. In some embodiments, the recited layers of the electrochromic element are contacting one another in that order from bottom to top. Alternative arrangements of the layers of the electrochromic element are also contemplated.

Generally, an electrochromic device comprises the electrochromic element described above, or elsewhere herein, and a power source in electrical communication with the first electrode and the second electrode, to provide an electric potential to the electrochromic device.

There are many potential configurations for the electrochromic device. One potentially useful configuration is depicted in FIG. 2. In FIG. 2, an electrochromic device, such as device 110, comprises (e.g., in the order depicted): a first electrode layer 112, which is a conductive layer; an electrochromic layer 114, comprising an electrochromic material; an insulating layer 116, which may also be termed a blocking layer, a barrier layer or a tunneling layer, and which comprises an electrically insulative material; a BHJ layer 118, comprising a composite that includes an electrochromic material and an electrically insulating material; a second electrode layer 120, which is a conductive material; and a power source, such as power source 134, which is in electrical communication with the first electrode and the second electrode. In some embodiments, the layers of the electrochromic device are in electrical and optical communication with one another. In some embodiments, the electrochromic layer and the bulk heterojunction layer of the electrochromic device may change from a first state (clear or transparent) to a second state (colored or darkened). In some embodiments, the electrochromic device may further comprise a protective layer (not shown).

In some embodiments, the layers of the device are disposed in the recited order from bottom to top. In some embodiments, the layers of the electrochromic device are contacting one another in that order from bottom to top. In some embodiments, the layers of the device are contacting one another in that order from top to bottom. Alternative arrangements of the layers of the electrochromic device are also contemplated.

The electrochromic elements and devices described herein comprise an electrode on, or adjacent to, the top and the bottom of the various electrochromic element or device layers. In some embodiments, the electrodes (“electrodes,” “the electrodes,” or a similar phrase is used as shorthand herein for “first electrode and/or second electrode”) may be formed on a substrate and/or an electrochromic layer. The electrodes may comprise a transparent material, which may also be conductive. When one or more of the electrodes are transparent, light and energy may be efficiently transmitted to the inner layers of the element or device and may interact with the electrochromic materials and other layers within the element or device.

In some embodiments, the electrochromic elements comprise a first electrode layer and a second electrode layer. The first electrode and the second electrode may be defined in their entirety by the electrode(s) found in these layers, or it is possible that the electrodes of these layers only partially define these layers. In some embodiments, the electrodes of these layers may be formed on a bonding layer and/or substrate. In some embodiments, the remainder of the electrode layers, wherein the electrodes only partially define these layers, may be formed of a transparent material. In some examples, when one or more of the electrodes and layers are transparent, light may be efficiently taken in from the outside of the layers to interact with the electrochromic material of the electrochromic element thereby enabling optical modulation of the electrochromic material with respect to emitted light.

In some examples, the electrodes may comprise a transparent conductive oxide, dispersed carbon nanotubes on a transparent substrate, metal wires arranged on a transparent substrate, or combinations thereof. In some embodiments, the electrodes may be formed from a transparent conductive oxide material having good transmissivity and conductivity, such as tin-doped indium oxide (also called indium tin oxide, or ITO), zinc oxide, gallium-doped zinc oxide (GZO), indium zinc oxide (IZO), aluminum-doped zinc oxide (AZO), tin oxide, antimony-doped tin oxide (ATO), fluorine-doped tin oxide (FTO), niobium-doped titanium oxide (TNO), a conductive polymer material, or a material containing Ag, Ag nanoparticles, carbon nanotubes or graphene. Of the transparent conductive oxide materials identified above, FTO may be selected for heat resistance, reduction resistance, and conductivity and ITO may be selected for conductivity and transparency. In the event a porous electrode is formed and calcined, then the transparent conductive oxide, if used, preferably has high heat resistance. One or more of the electrodes may contain one of these materials, or one or more of the electrodes may have a multi-layer structure containing a plurality of these materials. In an alternative form, one or more of the electrodes may be formed from a reflective material such as a Group 10 of 11 metal, non-limiting examples of which include Au, Ag, and/or Pt. Forms in which the reflective material is a Group 13 metal, such as aluminum (Al) are also possible.

In some embodiments, the first electrode is indium tin oxide. In some examples, the thickness of the first electrode (e.g., an ITO electrode) is about 10 nm to about 300 nm, about 10-12 nm, about 12-14 nm, about 14-16 nm, about 16-18 nm, about 18-20 nm, about 20-22 nm, about 22-24 nm, about 24-26 nm, about 26-28 nm, about 28-30 nm, about 30-35 nm, about 35-40 nm, about 40-50 nm, about 50-60 nm, about 60-70 nm, about 70-80 nm, about 80-90 nm, about 90-100 nm, about 100-110 nm, about 110-120 nm, about 120-130 nm, about 130-140 nm, about 140-150 nm, about 150-160 nm, about 160-170 nm, about 170-180 nm, about 180-190 nm, about 190-200 nm, about 200-210 nm, about 210-220 nm, about 220-230 nm, about 230-240 nm, about 240-250 nm, about 250-260 nm, about 260-270 nm, about 270-280 nm, about 280-290 nm, about 290-300 nm, about 75-85 nm, about 15-25 nm, about 1-50 nm, about 50-100 nm, about 100-150 nm, about 80 nm, about 20 nm, about 185 nm, or about any thickness bounded by any of the above ranges.

In some embodiments, the second electrode is indium tin oxide. In some examples, the thickness of the second electrode (e.g., an ITO electrode) is about 10 nm to about 150 nm, about 10-12 nm, about 12-14 nm, about 14-16 nm, about 16-18 nm, about 18-20 nm, about 20-22 nm, about 22-24 nm, about 24-26 nm, about 26-28 nm, about 28-30 nm, about 30-35 nm, about 35-40 nm, about 40-50 nm, about 50-60 nm, about 60-70 nm, about 70-80 nm, about 80-90 nm, about 90-100 nm, about 100-110 nm, about 110-120 nm, about 120-130 nm, about 130-140 nm, about 140-150 nm, about 15-25 nm, about 1-50 nm, about 50-100 nm, about 100-150 nm, about 80 nm, or about 20 nm.

Some embodiments include electrochromic elements or electrochromic devices comprising an electrochromic (EC) layer and a bulk heterojunction (BHJ) layer. The electrochromic layer of the elements and devices described herein comprise electrochromic materials containing charge sensitive materials. In some embodiments, the EC layer and the BHJ layer of the electrochromic element or device comprise one or more optical properties that may change from a first state (clear or transparent) to a second state (colored or darkened) upon the application of an electric potential. In some embodiments, the electrochromic material of the electrochromic layer may include p-type electrochromic materials. As used herein, the term “p-type electrochromic material” refers to a material in which its Fermi energy level (E_{f}) is closer to the valence band energy level (Eᵥ) than its conductance band energy level (E_{c}). In some embodiments, the electrochromic material of the BHJ layer may include n-type electrochromic materials. As used herein, the term “n-type electrochromic material” means the refers to a material in which its Fermi energy level (E_{f}) is closer to the conductance band energy level (E_{c}) than its valence band energy level (E_{f}).

Table 1 illustrates some electrochromic materials' E_{c}, Eᵥ, and E_{f}. This table is only for illustrative purposes and in no way is intended to limit the electrochromic materials that may be used in the current element.

TABLE 1

| | MoO₃ | V₂O₅ | WO₃ | Ta₂O₅ | NiO |
|---|---|---|---|---|---|
| E_{c} (eV) | −6.7 | −6.7 | −6.5 | −4.03 | −2.1 |
| Eᵥ (eV) | −9.7 | −9.5 | −9.8 | −7.93 | −5.3 |
| E_{f} (eV) | −6.9 | −7.0 | −6.7 | −4.45 | −4.7 |
| Material Type | n-type | n-type | n-type | n-type | p-type |

In some embodiments, the electrochromic layer may comprise p-type electrochromic materials. The term “p-type electrochromic material” or a similar term is used as shorthand for “p-type electrochromic material” or “p-type electrochromic-based composite.” A “p-type electrochromic-based composite” comprises a p-type electrochromic material an additive material comprising an inorganic oxide. In some embodiments, the electrochromic layer may comprise a p-type electrochromic material or a combination of a p-type electrochromic material and an additive inorganic oxide. In some embodiments, the electrochromic layer may allow holes to be injected from the transparent conductive material of the first electrode layer (anode) into the p-type electrochromic material. The injection of holes into the p-type electrochromic material significantly enhances the oxidation of the p-type electrochromic material causing a transformation from a first state (transparent) to a second state (darkened). In some embodiments, the p-type electrochromic materials may comprise anodic materials. The term “anodic electrochromic material” as used herein means a material that undergoes changes in optical properties by an oxidation reaction thereof in which electrons are removed from the material.

The electrochromic layer may be crystalline. In some examples, when the p-type electrochromic material crystalizes it forms a nanostructure or rough surface morphology. In cases where the p-type electrochromic material forms a nanostructured or rough surface morphology, the electrochromic layer may perform a dual function and operate as both the electrochromic layer and as the buffer layer. When the electrochromic layer operates in this dual capacity, the nanostructured or rough surface morphology may be transferred through the ultrathin layers of the element and imparted onto the surface of the second electrode layer. In some embodiments, the electrochromic layer may be amorphous or quasi amorphous. Amorphous or quasi amorphous first electrochromic layers have been found to possess better durability under some conditions, in comparison to their crystalline counterparts. The amorphous or quasi amorphous state of the first electrochromic layer may be obtained by the addition of an additive inorganic oxide (additive material) to the electrochromic material. In some embodiments, the additive inorganic oxide may be a post transition metal or a metalloid. It is believed that the addition of the additive inorganic oxide to the p-type electrochromic material breaks up the ordered lattice structure of the p-type electrochromic material, preventing the formation of a crystalline morphology. This interference with the lattice structure leads to an amorphous morphology. It is further believed that an amorphous surface stabilizes the electrochromic layer which in turn leads to improved device performance in certain conditions. It is further believed that by preventing such crystallization of the p-type electrochromic material stabilizes the % T modulation and increases the durability of the film.

Non-limiting examples of anodic electrochromic materials, e.g., for use in the electrochromic layer, include nickel oxide (NiO), iridium(IV) oxide (IrO₂), chromium oxide (Cr₂O₅), manganese dioxide (MnO₂), iron oxide (FeO₂), and cobalt(II) peroxide (CoO₂). In some embodiments, the electrochromic layer comprises nickel oxide. In some embodiments, the electrochromic layer may comprise a nickel-aluminum-oxide. In other embodiments, the electrochromic layer may comprise a nickel-silicon-oxide.

Some non-limiting additive inorganic oxides, e.g., for use in the electrochromic layer, such as an amorphous or a quasi-amorphous electrochromic layer, include titanium dioxide (TiO₂), aluminum oxide (Al₂O₃), tungsten oxide (WO₃), copper oxide (CuO), vanadium oxide (V₂O₅), cobalt oxide (CoO), silicon oxide (SiO₂), boron oxide (B₂O₂), and tin oxide (SnO₂). In some embodiments, the electrochromic layer may comprise nickel-aluminum-oxide. In some embodiments, the electrochromic layer may comprise nickel-silicon-oxide.

The electrochromic layer (e.g., a layer comprising nickel-aluminum-oxide (Ni—Al—O, or NiO with Al₂O₃) or nickel-silicon-oxide (Ni—Si—O, or NiO with SiO₂) or another metal oxide with an additive inorganic oxide above, may comprise an atomic ratio of additive inorganic oxide to Ni of about 1:19, or about 1:19 to 1:18, about 1:18 to 1:17, about 1:17 to 1:16, about 1:16 to 1:15, about 1:15 to 1:14, about 1:14 to 1:13, about 1:13 to 1:12, about 1:12 to 1:11, about 1:11 to 1:10, about 1:10 to 1:9, about 1:9 to 1:8, about 1:8 to 1:7, about 1:7 to 1:6, about 1:6 to 1:5, about 1:5 to 1:4, about 1:4 to 1:3, about 1:3 to 1:2, about 1:2 to 1:1, about 1:18, about 1:17, about 1:16, about 1:15, about 1:14, about 1:13, about 1:12, about 1:11, about 1:10, about 1:9, about 1:8, about 1:7, about 1:6, about 1:5, about 1:4, about 1:3, about 1:2, about 1:1, or any ratio bound by the ranges listed herein above. In some embodiments, the first electrochromic layer comprises about 50 to 95% Ni. In some embodiments, the first electrochromic layer comprises about 5 to 50% of the additive inorganic oxide.

The electrochromic layer (e.g., a layer comprising NiO, Ni—Al—O, Ni—Si—O, or another metal oxide compound above) may have any suitable thickness, such as about 40-500 nm, about 40-50 nm, about 50-60 nm, about 60-70 nm, about 70-80 nm, about 80-90 nm, about 90-100 nm, about 100-110 nm, about 110-120 nm, about 120-130 nm, about 130-140 nm, about 140-150 nm, about 150-160 nm, about 160-170 nm, about 170-180 nm, about 180-190 nm, about 190-200 nm, about 200-210 nm, about 210-220 nm, about 220-230 nm, about 230-240 nm, about 240-250 nm, about 250-260 nm, about 260-270 nm, about 270-280 nm, about 280-290 nm, about 290-300 nm, about 300-350 nm, about 350-400 nm, about 400-450 nm, about 450-500 nm, about 80-100 nm, about 100-125 nm, about 125-150 nm, about 0.1-50 nm, about 50-100 nm, about 100-150 nm, about 0.1-60 nm, about 60-120 nm, about 120-180 nm, about 0.1-100 nm, about 100-300 nm, about 200-400 nm, about 300-500 nm, about 80 nm, about 100 nm, about 125 nm, about 150 nm, or about any thickness in a range bounded by any of these values. It is believed that in embodiments wherein the electrochromic layer's morphology is crystalline, the ultrathin layers of the elements and devices described herein are sufficiently thin to allow the transfer of the nanostructured or rough surface morphology therethrough to affect the resultant surface morphology upon the second electrode layer, imparting a template of the nanostructured or rough surface morphology thereon.

The electrochromic layer (e.g., a layer comprising Ni—Al—O or Ni—Si—O or another metal oxide with and inorganic additive above) may comprise an atomic percentage of inorganic additive oxide, such as Si or Al, from about 1% to about 80%, about 2-70%, about 3-60%, about 4-65%, about 5-50%, about 10-45%, about 15-40%, about 20-35%, about 25-30%, about 1-3%, about 3-4%, about 4-5%, about 5-6%, about 6-8%, about 8-10%, about 10-12%, about 12-15%, about 4-6%, about 9-11%, about 1-5%, about 5-10%, about 10-15%, about 15-20%, about 20-25%, about 25-30%, about 30-40%, about 40-50%, or about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, about 40%, about 41%, about 42%, about 43%, about 44%, about 45%, about 46%, about 47%, about 48%, about 49%, about 50%, or about any atomic percentage in a range bound by the ranges indicated herein above.

The electrochromic layer comprising the p-type electrochromic material or p-type electrochromic-based composite may be fixed to the first electrode layer in any suitable manner. The different options for fixing the electrochromic layer are possible because in this electrochromic layer, at the time of the adjustment of charge imbalance, charge exchange between the electrodes needs only to occur by electron or hole movement through the layers and not by physical movement of the layers themselves.

In some embodiments, the electrochromic element comprises a bulk heterojunction (BHJ) layer. In some embodiments, the BHJ layer comprises a composite. In some examples, the composite may comprise n-type electrochromic materials, as discussed above, and electrically insulating materials. In some embodiments, the n-type electrochromic materials may comprise cathodic materials. The term “cathodic electrochromic material” as used herein means a material that undergoes changes in optical properties by a reduction reaction thereof, in which electrons are given to the material. The electrically insulating material of the BHJ layer may comprise inorganic oxides. In some embodiments, the inorganic oxide may be a post transition metal or a metalloid. N-type electrochromic materials allow electrons to be injected from the transparent conductive material of the second electrode layer (cathode), while the electrically insulating material provides an internal barrier, allowing electron injection into the BHJ material when a driving force, such as the application of an electrical potential, is present. When an electrical potential is applied, a tunneling effect is created through the composite material allowing the electrons enter into the BHJ layer, thereby reducing the n-type electrochromic materials and resulting in transformation of the material from a first optical state (transparent) to a second optical state (dark). When no driving voltage is present, the electrons do not freely dissipate out of the BHJ material, due to barrier created by the insulating material, thus preventing discharge of the material and allowing for enhanced on-state retention time. In some examples, the BHJ layer is amorphous. In some examples, the BHJ layer is quasi amorphous. In some embodiments, amorphous BHJ layers may possess better ON-state retention times in comparison to their traditional counter-parts comprising only n-type electrochromic materials. It is believed that the addition of an inorganic oxide to the n-type electrochromic material breaks up the ordered lattice structure of the n-type electrochromic material, preventing the formation of a crystalline morphology. This interference with the lattice structure leads to an amorphous morphology. It is further believed that an amorphous surface stabilizes the electrochromic layer which in turn leads to improved device performance in certain conditions.

Non-limiting examples of cathodic electrochromic materials include tungsten oxide (WO₃), titanium dioxide (TiO₂), niobium oxide (Nb₂O₅), molybdenum (VI) oxide (MoO₃), tantalum(V) oxide (Ta₂O₅), and vanadium pentoxide (V₂O₅). In some embodiments, the BHJ layer composite may comprise tungsten as one of the composite's components.

Some non-limiting electrically insulating inorganic material, e.g., for use in the amorphous or quasi amorphous BHJ layer include, for example, aluminum oxide (Al₂O₃), tantalum oxide (Ta₂O₃), yttrium oxide (Y₂O₃), hafnium oxide (HfO₂), calcium oxide (CaO), magnesium oxide (MgO), silicon oxide (SiO₂), silicon nitride (Si₃N₄) or aluminum nitride (AlN). In some embodiments, the BHJ layer may comprise tungsten-aluminum-oxide (W—Al—O). In some embodiments, the BHJ layer may comprise tungsten-silicon-oxide (W—Si—O).

The BHJ layer (e.g., a layer comprising tungsten-aluminum-oxide (W—Al—O), which is a composite of WO₃ and Al₂O₃; tungsten-silicon-oxide (W—Si—O), which is a composite of WO₃ and SiO₂; or a composite of another metal oxide and electrically insulating material above) may comprise an atomic ratio of the electrically insulating material (e.g., Al or Si) to tungsten (W) of about 1:19, or about 1:19 to about 1:18, about 1:18 to about 1:17, about 1:17 to about 1:16, about 1:16 to about 1:15, about 1:15 to about 1:14, about 1:14 to about 1:13, about 1:13 to about 1:12, about 1:12 to about 1:11, about 1:11 to about 1:10, about 1:10 to about 1:9, about 1:9 to about 1:8, about 1:8 to about 1:7, about 1:7 to about 1:6, about 1:6 to about 1:5, about 1:5 to about 1:4, about 1:4 to about 1:3, about 1:3 to about 1:2, about 1:2 to about 1:1, about 1:18, about 1:17, about 1:16, about 1:15, about 1:14, about 1:13, about 1:12, about 1:11, about 1:10, about 1:9, about 1:8, about 1:7, about 1:6, about 1:5, about 1:4, about 1:3, about 1:2, about 1:1, or any ratio bounded by any of the ranges listed herein above. In some embodiments, the BHJ layer comprises about 50% to 95% tungsten (atom %). In some embodiments, the BHJ layer comprises about 5% to 50% (atom %) of the electrically insulating material (e.g., Al or Si).

The BHJ layer (e.g., a layer comprising W—Al—O or W—Si—O or another metal oxide with and an electrically insulating material above) may comprise an atomic percentage of electrically insulating material (e.g., Al or Si) from about 1% to about 80%, about 2-70%, about 3-60%, about 4-65%, about 5-50%, about 10-45%, about 15-40%, about 20-35%, about 25-30%, about 1-3%, about 3-4%, about 4-5%, about 5-6%, about 6-8%, about 8-10%, about 10-12%, about 12-15%, about 4-6%, about 9-11%, about 1-5%, about 5-10%, about 10-15%, about 15-20%, about 20-25%, about 25-30%, about 30-40%, about 40-50%, or about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, about 40%, about 41%, about 42%, about 43%, about 44%, about 45%, about 46%, about 47%, about 48%, about 49%, about 50%, or about any atomic percentage bounded by any of the ranges indicated herein above.

The BHJ layer (e.g., comprising WO₃, W—Al—O, W—Si—O, or another metal oxide/electrically insulating material compound in the paragraph above) may have any suitable thickness, such as about 100-800 nm, about 100-110 nm, about 110-120 nm, about 120-130 nm, about 130-140 nm, about 140-150 nm, about 150-160 nm, about 160-170 nm, about 170-180 nm, about 180-190 nm, about 190-200 nm, about 200-210 nm, about 210-220 nm, about 220-230 nm, about 230-240 nm, about 240-250 nm, about 250-260 nm, about 260-270 nm, about 270-280 nm, about 280-290 nm, about 290-300 nm, about 300-310 nm, about 310-320 nm, about 320-330 nm, about 330-340 nm, about 340-350 nm, about 350-360 nm, about 360-370 nm, about 370-380 nm, about 380-390 nm, about 390-400 nm, about 400-410 nm, about 410-420 nm, about 420-430 nm, about 430-440 nm, about 440-450 nm, about 450-460 nm, about 460-470 nm, about 470-480 nm, about 480-490 nm, about 490-500 nm, about 500-550 nm, about 550-600 nm, about 600-650 nm, about 650-700 nm, about 700-750 nm, about 750-800 nm, about 100-300 nm, about 200-400 nm, about 300-500 nm, about 500-700 nm, about 600-800 nm, about 150-250 nm, about 250-350 nm, about 350-450 nm, about 100 nm, about 150 nm, about 200 nm, about 400 nm, or about any thickness in a range bounded by any of these values, although other variations are contemplated.

In some embodiments, the BHJ layer comprising the electrochromic materials and electrically insulating materials may be fixed to the second electrode layer by any suitable method. The different options for fixing the BHJ layer are possible because in this layer, at the time of the adjustment of charge imbalance, charge exchange between the electrodes needs only to occur by electron or hole movement through the layers and not by physical movement of the layers themselves. The BHJ layer may also be fixed to the insulating layer by any suitable method. Non-limiting methods of fixing the BHJ layer involve, for example, bonding the BHJ material (the n-type electrochromic material and the electrically insulating material) to the insulating layer through a functional group in a molecule of the electrochromic material, causing the insulating material to retain the electrochromic material in a comprehensive manner (e.g., in a film state) through the utilization of a force, such as an electrostatic interaction, or causing the electrochromic material to physically adsorb to the insulative material of the insulating layer. A method involving chemically bonding a low-molecular weight organic compound serving as the electrochromic material to a porous insulative material through a functional group thereof, or a method involving forming a high-molecular weight compound serving as the electrochromic material on the insulative material may be used when a quick reaction of the electrochromic material is desired. The former method may include fixing the low-molecular weight organic compound serving as the electrochromic material onto a fine particle oxide electrode, such as aluminum oxide, titanium oxide, zinc oxide, or tin oxide, through a functional group, such as an acid group (e.g., a phosphoric acid group or a carboxylic acid group). The latter method may include, for example, a method involving polymerizing and forming a viologen polymer on an insulative material and may include electrolytic polymerization. Similar methods are contemplated for fixing the electrochromic layer to the first electrode, and to the insulating layer.

In some embodiments, the electrochromic element comprises an insulating layer. In some embodiments, the insulating layer comprises an electrically insulating material characterized by at least one of a band gap of at least 5 eV, e.g., 8.7 eV (Al₂O₃), 5.6 eV (Y₂O₃), 5.8 eV (HfO₂) and/or 5.8 eV (ZrO₂), a conductance band minimum of at least 2 eV relative to the material's Fermi level, e.g., 8.7 eV (Al₂O₃), 2.8 eV (Y₂O₃), 2.5 eV (HfO₂), and/or 2.36 eV (ZrO₂), or a relative dielectric constant of at least 5 eV e.g., 9 eV (Al₂O₃), 15 eV (Y₂O₃), 25 eV (HfO₂), and/or 25 eV (ZrO₂). In the illustrated form (FIGS. 1 and 2), the electrochromic material of the electrochromic layer is isolated from the electrochromic material of the BHJ layer by the insulating layer. In some embodiments, the insulating layer blocks electronic charges (e.g., electrons and holes) from moving through the element or device from one electrode to the other, while retaining the injected electrons from the cathode within the electrochromic material of the BHJ layer, and retaining the injected holes from the anode within the electrochromic material of the electrochromic layer, resulting in the coloration or darkening of the electrochromic layers. Further, the first electrode layer may also be electrically isolated or separated from the BHJ layer by the insulating layer, which includes an electrically insulative material. The term “electrically insulative” refers to the reduced transmissivity of the layer to electrons and/or holes. In one form, the electrical isolation or separation between these layers may result from increased resistivity within the insulating layer. In addition, it should be appreciated that the first electrode may be in electrical communication with the electrochromic layer, which may be in electrical communication with the insulating layer, which may be in electrical communication with the BHJ layer, which may be in electrical communication with the second electrode layer. As indicated above, the insulating layer may include one or more electrically insulative materials, including inorganic and/or organic materials, which exhibit electrically insulative properties. It is believed that the electrically insulative properties of the insulating layer comes from materials with a large “band gap” or “electrical gap” (the energy difference in electron volts (eV) between the top of the valence band and the bottom of the conductive band) and a high conductance band minimum. When the insulative material has a large band gap and high conductance band minimum, very few electrons contain the energy to surmount the electrical gap in order to move freely through the insulative material and thus are blocked at the interface of the insulating material and the BHJ layer's material. It is believed that this blockage leads to an accumulation of electrons within the BHJ layer resulting in higher coloration or darkness efficiency due to the increase in the reduction of the n-type electrochromic materials caused by the excess electrons. It is believed that by using an insulating material having a large band gap and a large conductance band minimum value, the insulating layer blocks electrons from the cathode from passing through the insulating layer, thus trapping the electrons within the BHJ layer where they localize and aid in the reduction of the n-type electrochromic material causing a change in the material's optical properties from a first state (transparent) to a second state (dark). It is also believed that the use of the insulative materials with a large band gap block the holes from entering the insulative material, resulting in an accumulation of holes within the p-type electrochromic material, aiding in the oxidation of the p-type electrochromic material and causing a change in the material's optical properties from a first state (transparent) to a second state (dark). It is further believed that the utilization of materials with high dielectric constants result in higher charge storage within the p-type and n-type electrochromic materials. It is believed that this increase in the stored charge leads to enhanced reduction of the n-type electrochromic material resulting in a darker second state and enhanced oxidation of the p-type electrochromic materials, also resulting in a darker second state. It is further believed that the higher charge storage results in a lower light transmittance. It may be that the cumulative effect of blocking both the holes and the electrons from passing into the insulative layer, and increasing the stored charge within the electrochromic layers' materials, allows for the use of ultrathin layers of p-type electrochromic materials of the EC layer, n-type electrochromic materials of the BHJ layer, and insulative materials within the electrochromic elements and devices of the present disclosure.

In some embodiments, the insulating layer may be formed, in whole or in part, by oxide, nitride, and/or fluoride compounds, such as, for example, aluminum oxide (Al₂O₃), tantalum oxide (Ta₂O₃), yttrium oxide (Y₂O₃), hafnium oxide (HfO₂), calcium oxide (CaO), magnesium oxide (MgO), silicon oxide (SiO₂) and/or zirconium oxide, Si₃N₄, AlN and lithium fluoride. In some embodiments, the insulating layer comprises aluminum oxide, yttrium oxide, hafnium oxide, zirconium oxide or tantalum oxide. In another embodiment, the insulating layer comprises a stoichiometric metal oxide compound, such as TiO₂, SiO₂, WO₃, Al₂O₃, Ta₂O₅, Y₂O₃, HfO₂, CaO, MgO or ZrO₂. In some embodiments, the insulating layer comprising non-stoichiometric metal oxide compounds are also contemplated. In some embodiments, the insulating layer may comprise aluminum oxide (Al₂O₃). In some embodiments, the insulating layer may comprise yttrium oxide (Y₂O₃). In some embodiments, the insulating layer may comprise hafnium oxide (HfO₂). In some embodiments, the insulating layer may comprise zirconium oxide (ZrO₂). In some embodiments, the insulating layer may comprise a doped zirconium oxide. In some embodiments, the insulating layer may comprise a doped silicon oxide (SiO₂). In cases where the insulating layer is doped, it may be doped with silicon (Si), aluminum (Al), zirconium (Zr), yttrium (Y) or combinations thereof. In some embodiments, the insulating layer may comprise silicon-aluminum-oxide (Si—Al—O). In some embodiments, insulating layer may comprise zirconium-yttrium-oxide (Zr—Y—O). In some embodiments, the insulating layer may comprise zirconium-aluminum-silicon-oxide (Zr—Al—Si—O). Any material, however, may be used for the insulating layer provided it may block the passage of electrons and holes from one passing out of the respective electrochromic materials.

In some embodiments, wherein the insulating layer comprises a stoichiometric metal oxide compound, the metal oxide compound further comprises a doping material. In some embodiments, the metal oxide doping material may be silicon oxide (SiO₂). In some embodiments, the amount of silicon oxide doped in the metal oxide (e.g. Al₂O₃) may be between 2 wt % to about 40 wt %, about 2-4 wt %, about 4-6 wt %, about 6-8 wt %, about 8-10 wt %, about 10-15 wt % about 15-20 wt %, about 20-25 wt %, about 25-30 wt %, about 30-35 wt %, about 35-40 wt %, about 4-6 wt %, about 15-25 wt % about 20 wt %, about 5 wt %, or any wt % within the ranges cited of the total weight of metal oxide.

The insulating layer may have any suitable thickness, such as about 40 nm to about 300 nm, about 40-50 nm, about 50-60 nm, about 60-70 nm, about 70-80 nm, about 80-90 nm, about 90-100 nm, about 100-110 nm, about 110-120 nm, about 120-130 nm, about 130-140 nm, about 140-150 nm, about 150-160 nm, about 160-170 nm, about 170-180 nm, about 180-190 nm, about 190-200 nm, about 200-210 nm, about 210-220 nm, about 220-230 nm, about 230-240 nm, about 240-250 nm, about 250-260 nm, about 260-270 nm, about 270-280 nm, about 280-290 nm, about 290-300 nm, about 70-90 nm, about 90-110 nm, about 110-130 nm, about 130-150 nm, about 140-160 nm, about 40-80 nm, about 80-120 nm, about 120-160 nm, about 40-100 nm, about 100-160 nm, about 80 nm, about 100 nm, about 140 nm, about 150 nm, or about any thickness in a range bounded by any of these values. In some embodiments, the insulating layer may have a thickness which is less than, equal to, or greater than the thickness of the electrochromic layer and/or the BHJ layer. In some examples, the insulating layer comprises materials and/or structures that are effective in confining, on a selective basis, electrons and/or holes within the adjacent electrochromic and BHJ layers. It is believed that confining the electrons and/or holes within their respective layers may significantly increase the reduction and/or oxidation of the metal oxide electrochromic material leading to a lower percentage of transmittance (T %) at the second (darkened) state.

In some embodiments, the insulating layer may be effective for maintaining (in whole or in part) charges injected in the electrochromic materials of the adjacent electrochromic layers to be stored under a no bias condition; i.e., without continued application of an electric potential.

In some embodiments, the electrochromic layer may comprise a nanostructured or rough surface morphology. In some embodiments, the electrochromic layer may have a dual function by operating as a buffer layer and a p-type electrochromic layer. This dual function of the electrochromic layer may be achieved by using a suitable annealing process.

As detailed above, the BHJ layer comprises a composite of electrochromic material and electrically insulating material. In one particular, but non-limiting, form the electrochromic material includes a metal oxide such as WO₃. However, it should be appreciated that the EC and BHJ layers may include any electrochromic material or compound that changes optical transmittance and/or absorption when a voltage pulse above a threshold value is applied.

In some embodiments, the electrochromic device may comprise a protection layer. In some embodiments, the protection layer may comprise a polymer or other material to protect the electrochromic device from moisture, oxidation, physical damage, etc. Suitable protective layers and or materials are described in the art.

It is contemplated that the electrochromic elements and devices herein could be used for a number of different purposes and applications. In one non-limiting form, for example, the electrochromic elements and devices herein could be used in a window member that includes a pair of transparent substrates with the electrochromic elements and devices described herein positioned between said transparent substrates. Owing to the presence of the electrochromic element or device of the present disclosure, the window member may adjust the quantity of light transmitted through the window member bearing the transparent substrates. In addition, the window member may include a frame which supports the electrochemical element or device of the current disclosure, and the window member may be used in an aircraft, an automobile, a house, an office building, or the like, just to provide a few possibilities. In some embodiments, the window member comprising the electrochemical element or device of the present disclosure may effect a difference in the transmission of light therethrough of at least 10%, at least 20%, at least 30%, at least 40%, at least 45%, at least 50%, at least 55%, at least 60%, at least 65%, at least 70%, at least 75%, at least 80%, at least 85%, at least 90%, at least 95%, or about 95%400%, between the off and on state at a selected wavelength in the visible range of light.

It is also contemplated that the electrochromic elements and devices herein could be used in a non-limiting form, which includes building windows, vehicle windows, dynamic camera shutters, and eyeglasses. For example, the electrochromic element and devices could be used in eye glass member that includes a pair transparent lenses with the electrochromic elements or devices described herein positioned upon one surface of each lens. Owing to the presence of the electrochromic element or device of the present disclosure, the lens of the eye glass member may adjust the quantity of light transmitted through the lens.

In some embodiments, activation of or turning on the electrochromic materials of the EC layer and the BHJ layer involves injecting holes into the electrochromic layer while electrons are injected into the BHJ layer as the second electrode is held at a ground potential and a positive voltage is applied to the first electrode. When a forward DC voltage bias is applied to the device (the electrical potential of the first electrode is higher than the second electrode), holes injected from the first electrode into the p-type electrochromic material of the EC layer increase its coloration or decrease its transparency (1%), while electrons injected from the second electrode into the n-type electrochromic material of the BHJ layer increase its coloration or decrease its transmittance (1%). When a reversed voltage bias is applied to the device (the electrical potential of the second electrode is higher than the electrical potential of the first electrode), electrons are removed from the n-type electrochromic material of the BHJ layer, decreasing the discoloration or increasing its light transmittance (1%), and holes are removed from the p-type electrochromic material EC layer, decreasing the discoloration or increasing its light transmittance (1%). The applied DC electrical voltage may be from 0.1V up to 5V or higher depending on how the devices are made.

While operation of the present disclosure has been described principally in connection with the electrochromic devices described herein, it is believed that the operating principles of the electrochromic devices and electrochromic elements described herein are the same. In FIG. 2, a voltage pulse is applied to the first electrode and the second electrode. Since the device is insulated under normal operation, the applied voltage pulse is only needed for switching states of the electrochromic material of the electrochromic layer and electrochromic material of the BHJ layer. Further, as indicated above, electron and/or hole conduction may only occur upon application of a threshold voltage pulse necessary to push electrons and/or holes into or out of the electrochromic material of the EC layer and the BHJ layer. Moreover, given that the device is insulated under normal operation and the electrochromic material of the EC layer and the BHJ layer is insulated from the electrodes and/or holes, the leakage of charges into or out of the electrochromic material of the EC layer and the BHJ layer is reduced, minimized, or eliminated.

The insulating effect of the insulating/blocking layer of the present disclosure may provide a wide band gap insulating effect, while the electrochromic layers have a lower-level conduction band that may keep the electron[s] trapped therein as the “memory” effect (non-volatile), which reduces, minimizes and/or insures no power consumption under normal device operation unless a switching process is occurring. Similarly, this arrangement may reduce, minimize and/or eliminate the issue of leakage suffered in other forms of electrochromic devices. In addition, the insulative properties of the devices described herein allow the voltage applied from the power supply to the electrochromic material of EC layer and BHJ layer to be uniformly applied without a potential drop to the electrode, since the resistance of the device is much larger than the resistance of the electrode. Other forms of an electrochromic device may generally be highly conductive and, in applications for a larger area such as a window, the device has a much lower resistance and the electrode layer's resistance may be comparable to or less than the device's resistance. This may result in a drop across the electrode layer, which may cause non-uniformity in application of the power supply for applications of these devices in larger area applications. In contrast, as indicated above, it is believed the electrochromic elements and electrochromic devices of the present disclosure may be effective for minimizing, reducing, or eliminating the occurrence of this issue.

In some embodiments of the present disclosure, the electrochromic material of the EC layer may trap both electrons and holes. When a voltage pulse is supplied to the two electrodes above a threshold value, the large band gap of the insulating layer may cause electron injection from the cathode electrode into the electrochromic material of BHJ layer and hole injection from the anode into the EC layer. The charges will be stored in the respective electrochromic materials due to the insulative effect provided by the insulating layer. The stored charges in the electrochromic material of EC and BHJ layers may cause a color change or a change in transmission/absorption. For example, it may cause a change from a first state that is transparent or clear, to a second state that has high absorption or darkened.

Some embodiments include a method for preparing an electrochromic device. In this method an electrochromic (EC) layer comprising a p-type electrochromic material and optionally an additive comprising an inorganic oxide is deposited upon and in electrical communication with the first electrode layer; an insulating layer comprising an electrically insulating material is deposited upon and in electrical communication with the EC layer; a bulk heterojunction (BHJ) layer comprising a composite comprising an n-type electrochromic material and electrically insulating material is deposited upon and in electrical communication with the insulating layer; and a second electrode layer comprising transparent conductive material with a nanostructure surface morphology is deposited upon and in electrical communication with the BHJ layer. In some embodiments of the method, the p-type electrochromic material of the EC layer may comprise a nanostructure surface morphology. In some embodiments of the method, the p-type electrochromic material with a nanostructure surface morphology operates as both the buffer layer and as the electrochromic layer. In other embodiments of the method, the second electrode layer may have a thickness between about 10 nm to about 500 nm to allow the transfer of the nanostructure surface morphology from the EC layer, imparting a complementary nanostructured surface morphology onto the transparent conductive material.

Some methods for preparing an electrochromic device further comprise electrically connecting the transparent conductive material of the first electrode layer and the transparent conductive material of the second electrode layer to a power source, wherein the first electrode layer and the second electrode layer are in electrical communication. In other embodiments, the method further comprises a tunneling layer disposed between the second electrode layer and the BHJ layer.

Some methods for preparing an electrochromic device may further comprise encapsulating the device with an optically transparent encapsulation material, which may also be referred to as a protective layer. The optically transparent encapsulating material may be oxygen limiting or preventing, not allowing, or greatly reducing the exposure to atmospheric oxygen. The choice of encapsulating material is not limiting, and one skilled in the art of electrochromic devices could choose which encapsulating material to use.

### Embodiments

Embodiment 1. An electrochromic element comprising:
   a first electrode layer, wherein the first electrode layer comprises a transparent conductive material;
   an electrochromic layer, wherein the electrochromic layer comprises a p-type electrochromic material, and wherein the electrochromic layer is in electrical communication with the insulating layer;
   an insulating layer, wherein the insulating layer comprises an electrically insulating material with a band gap at least 5 eV and a conductance band edge with a minimum of 2 eV relative to the insulating materials Fermi level and wherein the electrically insulating material is in electrical communication with the electrochromic layer;
   a bulk heterojunction layer, wherein the bulk heterojunction comprises a composite comprising a n-type electrochromic material and an electrically insulating material, wherein the bulk heterojunction layer is in electrical communication with the insulating layer; and
   a second electrode layer, wherein the first electrode layer comprises a transparent conductive material and wherein the second electrode layer is in electrical communication with the bulk heterojunction layer.
Embodiment 2. The electrochromic element of embodiment 1, wherein the p-type electrochromic material further comprises an inorganic oxide.
Embodiment 3. The electrochromic element of embodiment 2, wherein the inorganic oxide is a post translational metal or a metalloid.
Embodiment 4. The electrochromic element of embodiment 1, wherein p-type electrochromic material comprises an anodic material.
Embodiment 5. The electrochromic element of embodiment 1, wherein the p-type electrochromic material comprises nickel-oxide.
Embodiment 6. The electrochromic element of embodiment 1, wherein the electrically insulating material of the bulk heterojunction layer comprises and inorganic oxides.
Embodiment 7. The electrochromic element of embodiment 6, wherein the inorganic oxide is aluminum.
Embodiment 8. The electrochromic element of embodiment 1, wherein the inorganic oxide is a metalloid.
Embodiment 9. The electrochromic element of embodiment 7, wherein the metalloid is silicon-dioxide.
Embodiment 10. The electrochromic element of embodiment 1, wherein the n-type electrochromic material is tungsten oxide.
Embodiment 11. The electrochromic element of embodiment 1, wherein the bulk heterojunction comprises tungsten-aluminum oxide.
Embodiment 12. The electrochromic element of embodiment 1, wherein the bulk heterojunction layer is amorphous.
Embodiment 13. The electrochromic element of embodiment 1, wherein the bulk heterojunction layer comprises about 70 to about 99 atomic % of n-type electrochromic material.
Embodiment 14. The electrochromic element of embodiment 1, wherein the bulk heterojunction layer comprises about 1 to 50 atomic % of electrically insulating material.
Embodiment 15. A method for preparing an electrochromic device the method comprising:
Providing a first electrode layer comprising a transparent conductive material;
An electrochromic layer, comprising a p-type electrochromic material, deposited upon and in electrical communication with the first electrode layer;
an insulating layer comprising an electrically insulating material deposited upon and in electrical communication with the electrochromic layer;
a bulk heterojunction layer comprising a n-type electrochromic material and an electrically insulating material, deposited upon and in electrical communication with the insulating layer; and
a second electrode layer comprising a transparent conductive material with a nanostructured surface morphology deposited upon and in electrical communication with the bulk heterojunction layer.
Embodiment 16. An electrochromic device comprising;
   The electrochromic element of embodiments 1, 2, 3, 4, 5, 6, 7, 8, 9, 10, 11, 12, 13, or 14; A power source in electrical communication with electrochromic layer and the bulk heterojunction layer of the electrochromic element, wherein the power source provides an electrical voltage to the device.

### Examples

It should be appreciated that the following Examples are for illustration purposes and are not intended to be construed as limiting the subject matter disclosed in this document to only the embodiments disclosed in these examples.

### Preparing Electrochromic Device CE-1

A pre-learned patterned ITO-glass substrate (first electrode/anode) was loaded onto a sputtering deposition chamber (Angstrom Engineering, Inc.) set at 2×10⁻⁷ torr. For device CE-1, first a Ni—Al (5%)-O (100 nm), p-type, electrochromic layer was deposited under vacuum of 2×10⁻⁷ torr, from a Ni—Al (5%) target under a working gas of Ar—O₂, where O₂ concentration was set at 30% with a deposition rate of 2 Å/s. Next, a Si—Al₂O₃ (100 nm) insulation layer was deposited under vacuum of 2×10⁻⁷ torr, where the O₂ concentration was set at 15% with a deposition rate of 3 Å/s. The insulating layer was deposited on the p-type electrochromic layer through reactive sputtering of a Si—Al target under working gas of Ar—O₂, with the O₂ concentration of 15% and a deposition rate of A/s. Next, a WO₃ (200 nm) n-type, electrochromic layer was deposited under vacuum of 2×10⁻⁷ torr, from a tungsten (W) target under a working gas of Ar:O₂, where O₂ concentration was set at 35% with a deposition rate of 3 Å/s. Next, the ITO electrode (second electrode/cathode) was deposited at a deposition rate of 1.5 Å/s. Electrical connections were connected between a power source (Tektronix, Inc., Beaverton, Oreg., USA, Kethley 2400 source meter) and switched electrical connections with the electrodes to enable selective application of potential to the first electrode (on) or to the bottom or second electrode (off).

The devices of Examples, EC-1 through EC-3 were made in a manner similar to that described above except the bulk heterojunction layer varied as indicated in Table 2 below.

TABLE 2
Electrochromic Devices

| | | | Electro- | | Second Electro- | |
|---|---|---|---|---|---|---|
| | | First | chromic | Insulating | chromic layer/BHJ | Second |
| Example | Substrate | Electrode | layer | layer | layer | Electrode |
| CE-1 | Glass | ITO | Al₂O₃ (5%) NiO | Si (5%)—Al₂O₃ | WO₃ | ITO |
| | | | (100 nm) | (100 nm) | (200 nm) | (80 nm) |
| EC-1 | Glass | ITO | Al₂O₃ (5%) NiO | Si (5%)—Al₂O₃ | W—Al(5%)—O | ITO |
| | | | (100 nm) | (100 nm) | (200 nm) | (80 nm) |
| EC-2 | Glass | ITO | Al₂O₃ (5%) NiO | Si (5%)—Al₂O₃ | W—Al(10%)—O | ITO |
| | | | (100 nm) | (100 nm) | (200 nm) | (80 nm) |
| EC-3 | Glass | ITO | Al₂O₃ (5%) NiO | Si (5%)—Al₂O₃ | W—Al(10%)—O | ITO |
| | | | (100 nm) | (100 nm) | (200 nm) | (80 nm) |

### Transmissive (T %)

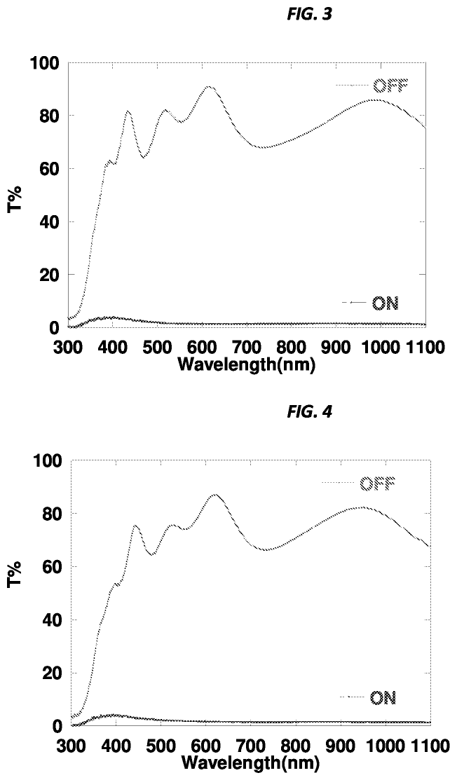

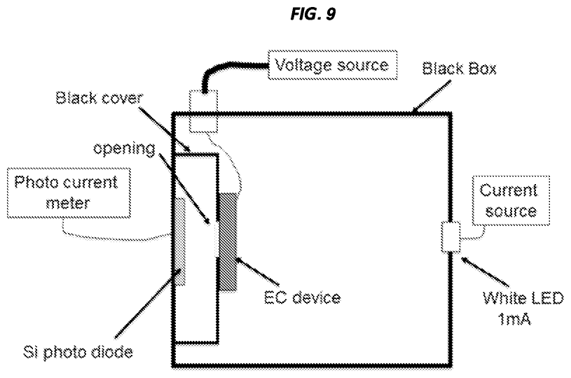

In addition, total light transmittance data of the examples were measured by using the measurement system like that described in U.S. Pat. No. 8,169,136 (shown there and described in FIG. 9 (MCPD 7000, Otsuka Electronics, Inc., Xe lamp, monochromator, and integrating sphere equipped). FIGS. 3-4 show the total light transmittance spectrum of the ON state and OFF state of embodiments tested, e.g., Samples CE-1, and EC-2.

The Example CE-1 device as described herein was positioned onto a Filmetrics F10-RT-YV reflectometer (Filmetrics, San Diego, Calif., USA), and the total transmission therethrough (T %) for ON state and OFF state was determined over varying wavelengths of light. The T % ON state and OFF state for fresh and accelerated aged (see below) devices with CE-1, and EC-2, are shown in FIGS. 3 and 4, respectively. At 630 nm, they showed a difference between on and off state T %, at 630 nm of 87.7% (FIG. 3, CE-1 fresh); of 84.5% (FIG. 4, fresh EC-2). As shown, the T % of a device with a BHJ layer do not significantly change compared to a device with a conventional tungsten alone layer.

### Dark-State Retention Test

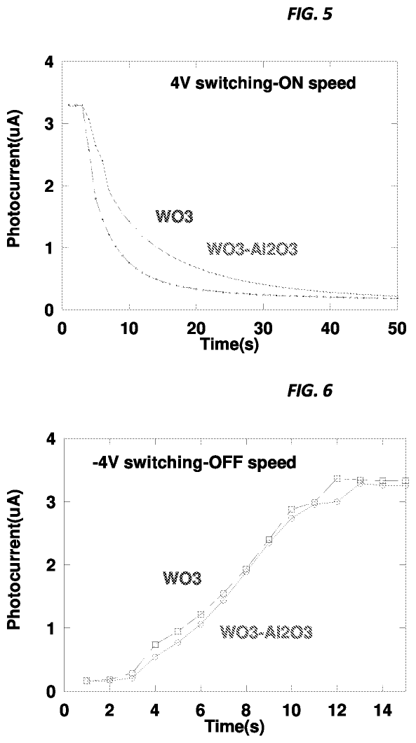

Dark-state retention time for the devices switching speeds, while under forward and reverse bias, were measured by using the measurement system like that described in U.S. Pat. No. 8,169,136 (shown there and described in FIG. 9 (MCPD 7000, Otsuka Electronics, Inc., Xe lamp, monochromator, and integrating sphere equipped). The electrochromic device being tested was first exposed to a forward bias (4V) causing the device to enter the dark-state (on-state) and allowed to stabilize. Next, the device was exposed to a negative bias (−4V) causing the device to switch from a dark (on) state to the clear (off) state. The photocurrent (μA) were measured and plotted (Photocurrent (μA) over time (sec.)). The results show the bulk heterojunction layered device operates almost as a conventional device, with the BHJ layer exhibiting only a slight delay in the initial on switching speed, but overall having the same performance as the photocurrent approaches 0 μA, FIG. 5, and almost identical results when switching to the off-state using a reverse bias, FIG. 6. manner as a traditional electrochromic device when there is a driving force (−4V) causing the electrons to tunnel out of the bulk heterojunction layer.

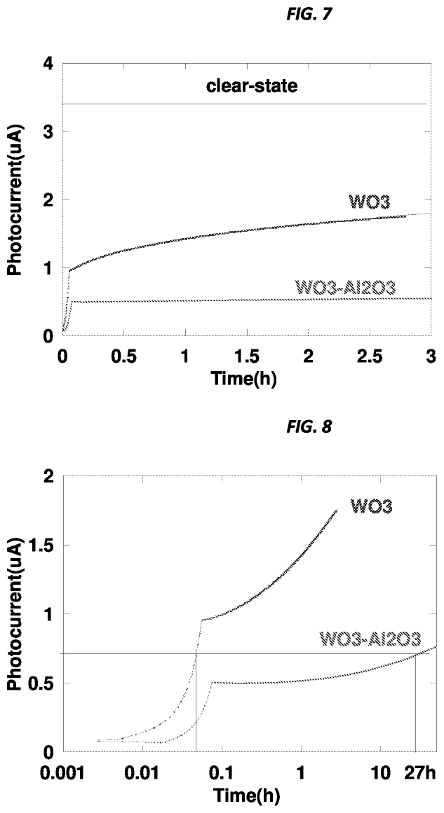

Next, the devices dark-state retention time for the devices switching speeds, when no reverse bias is applied, were measured. The electrochromic device being tested was again first exposed to a forward bias of 4V and allowed to stabilize in the dark-state (on). Then, with no reverse bias (0V) being applied, the device was allowed to return to the clear-state (off). The photocurrent was measured for the devices and plotted in log scale, (Photocurrent (μA) over time (sec.)), shown in FIGS. 7 & 8 (FIG. 7 plotted in linear phase and FIG. 8 plotted in log phase). The data indicates that the device without the BHJ layer allows the electrons to leak out of the WO₃ layer, reducing the dark state more rapidly than the device containing the BHJ layer. The results show that the without a reverse bias to tunnel the electrons out of the BHJ layer, the device retains the electrons within the bulk heterojunction's composite material enhancing the dark-state retention time relative to a conventional device. CE-1 takes about 0.5 hours for the T % increases by about 10% (or about 0.7 μA) as compared to EC-2 which takes about 27 hours to achieve about a 10% increase in its T %.

For the processes and/or methods disclosed, the functions performed in the processes and methods may be implemented in differing order, as may be indicated by context. Furthermore, the outlined steps and operations are only provided as examples, and some of the steps and operations may be optional, combined into fewer steps and operations, or expanded into additional steps and operations.

This disclosure may sometimes illustrate different components contained within, or connected with, different other components. Such depicted architectures are merely examples, and many other architectures may be implemented which achieve the same or similar functionality.

The terms used in this disclosure, and in the appended embodiments, are generally intended as “open” terms (e.g., the term “including” should be interpreted as “including, but not limited to,” the term “having” should be interpreted as “having at least,” the term “includes” should be interpreted as “includes, but is not limited to,” etc.). In addition, if a specific number of elements is introduced, this may be interpreted to mean at least the recited number, as may be indicated by context (e.g., the bare recitation of “two recitations,” without other modifiers, means at least two recitations, or two or more recitations). As used in this disclosure, any disjunctive word and/or phrase presenting two or more alternative terms should be understood to contemplate the possibilities of including one of the terms, either of the terms, or both terms. For example, the phrase “A or B” will be understood to include the possibilities of “A” or “B” or “A and B.”

The terms and words used are not limited to the bibliographical meanings but are merely used to enable a clear and consistent understanding of the disclosure. It is to be understood that the singular forms “a,” “an,” and “the” include plural referents unless the context clearly dictates otherwise. Thus, for example, reference to “a component surface” includes reference to one or more of such surfaces.

By the term “substantially” it is meant that the recited characteristic, parameter, or value need not be achieved exactly, but that deviations or variations, including for example, tolerances, measurement error, measurement accuracy limitations and other factors known to those skilled in the art, may occur in amounts that do not preclude the effect the characteristic was intended to provide.

Aspects of the present disclosure may be embodied in other forms without departing from its spirit or essential characteristics. The described aspects are to be considered in all respects illustrative and not restrictive. The subject matter of the present disclosure is indicated by the appended embodiments rather than by the foregoing description. All changes, which come within the meaning and range of equivalency of the embodiments, are to be embraced within their scope.

1. An electrochromic element comprising:
a first electrode layer comprising a transparent conductive material;
an electrochromic layer comprising a p-type electrochromic material, wherein the electrochromic layer is disposed over and in electrical communication with the first electrode layer;
an insulating layer comprising an electrically insulating material with a band gap at least 5 eV and a conductance band edge that is at least 2 eV higher than the electrically insulating material's Fermi level, wherein the electrically insulating material is disposed over and in electrical communication with the electrochromic layer;
a bulk heterojunction layer comprising a composite including an n-type electrochromic material and an electrically insulating material, wherein the bulk heterojunction layer is disposed over and in electrical communication with the insulating layer; and
a second electrode layer comprising a transparent conductive material, wherein the second electrode layer is disposed over and in electrical communication with the bulk heterojunction layer.

2. The electrochromic element of claim 1, wherein the first electrode layer comprises a transparent conductive metal oxide.

3. The electrochromic element of claim 2, wherein the transparent conductive metal oxide is indium tin oxide.

4. The electrochromic element of claim 1, wherein the second electrode layer comprises a transparent conductive metal oxide.

5. The electrochromic element of claim 4, wherein the transparent conductive metal oxide is indium tin oxide.

6. The electrochromic element of claim 1, wherein the p-type electrochromic material comprises an anodic material.

7. The electrochromic element of claim 1, wherein the p-type electrochromic material comprises nickel oxide.

8. The electrochromic element of claim 1, wherein the electrochromic layer further comprises an inorganic oxide.

9. The electrochromic element of claim 8, wherein the inorganic oxide is aluminum oxide.

10. The electrochromic element of claim 1, wherein the insulating layer comprises aluminum oxide and a doping material.

11. The electrochromic element of claim 10, wherein the doping material is silicon oxide.

12. The electrochromic element of claim 1, wherein the n-type electrochromic material of the bulk heterojunction layer comprises a cathodic material.

13. The electrochromic element of claim 1, wherein the n-type electrochromic material of the bulk heterojunction layer comprises tungsten oxide.

14. The electrochromic element of claim 1, wherein the electrically insulating material of the bulk heterojunction layer comprises an inorganic oxide.

15. The electrochromic element of claim 14, wherein the inorganic oxide is about 1 atomic % to about 50 atomic % of the bulk heterojunction layer.

16. The electrochromic element of claim 14, wherein the inorganic oxide is aluminum oxide.

17. The electrochromic element of claim 1, wherein the bulk heterojunction layer comprises tungsten-aluminum-oxide.

18. The electrochromic element of claim 1, wherein the bulk heterojunction layer is amorphous.

19. A method for preparing the electrochromic element of claim 1, the method comprising:
depositing the first electrode layer;
depositing the electrochromic layer over and in electrical communication with the first electrode layer;
depositing the insulating layer upon and in electrical communication with the electrochromic layer;
depositing the bulk heterojunction layer upon the insulating layer so that the bulk heterojunction layer is in electrical communication with the insulating layer; and
depositing the second electrode layer upon and in electrical communication with the bulk heterojunction layer, such that the second electrode layer has a nanostructured surface morphology.

20. An electrochromic device comprising:
the electrochromic element of claim 1; and
a power source in electrical communication with the first electrode layer and the second electrode layer of the electrochromic element, wherein the power source provides an electrical voltage to the device.
